(19) United States
(12) Patent Application Publication
(10) Pub. No.: US 2014/0065816 A1
(43) Pub. Date: Mar. 6, 2014

(54) DIELECTRIC FORMATION

(71) Applicants: Tsung-Jung Tsai, Taipei (TW); Hsin-Chieh Yao, Douliu City (TW); Chien-Hua Huang, Pingzhen City (TW); Chung-Ju Lee, Hsin-Chu (TW)

(72) Inventors: Tsung-Jung Tsai, Taipei (TW); Hsin-Chieh Yao, Douliu City (TW); Chien-Hua Huang, Pingzhen City (TW); Chung-Ju Lee, Hsin-Chu (TW)

(73) Assignee: Taiwan Semiconductor Manufacturing Company Limited, Hsin-Chu (TW)

(21) Appl. No.: 13/600,504

(22) Filed: Aug. 31, 2012

(51) Int. Cl. H01L 21/768

(52) U.S. Cl. 438/627; 257/E21.577

(57) ABSTRACT

Among other things, one or more techniques for forming a low k dielectric around a metal line during an integrated circuit (IC) fabrication process are provided. In an embodiment, a metal line is formed prior to forming a surrounding low k dielectric layer around the metal line. In an embodiment, the metal line is formed by filling a trench space in a skeleton layer with metal. In this embodiment, the skeleton layer is removed to form a dielectric space in a different location than the trench space. The dielectric space is then filled with a low k dielectric material to form a surrounding low k dielectric layer around the metal line. In this manner, damage to the surrounding low k dielectric layer, that would otherwise occur if the surrounding low k dielectric layer was etched, for example, is mitigated.

### BACKGROUND

Generally, an integrated circuit (IC) comprises one or more interconnects, one or more vias, one or more metal lines, and dielectric surrounding the vias and metal lines. For example, a metal line is connected to a via and a contact. Additionally, the metal line and via are surrounded by a dielectric. However, conventional trench formation for a metal line generally causes damage to the dielectric such that a dielectric constant (k) of the dielectric shifts in an undesirable manner. Moreover, this “k” shift is associated with a negative impact on R×C performance of the IC, for example.

### SUMMARY

This summary is provided to introduce a selection of concepts in a simplified form that are further described below in the detailed description. This summary is not intended to be an extensive overview of the claimed subject matter, identify key factors or essential features of the claimed subject matter, nor is it intended to be used to limit the scope of the claimed subject matter.

Among other things, one or more techniques for forming a dielectric around a metal line during an integrated circuit (IC) fabrication process are provided herein. In an embodiment, a metal line is formed prior to forming a surrounding low k dielectric layer surrounding the metal line. In an embodiment, the surrounding low k dielectric layer surrounding the metal line is formed after forming the metal line. Therefore, the surrounding low k dielectric layer surrounding the metal line is generally not damaged at least because no trench etch is required for forming the metal line.

In another embodiment, a metal line is formed by filling a trench space in a skeleton layer with metal. In this embodiment, the skeleton layer is removed to form a dielectric space, where the dielectric space is in a different location than the trench space. In an embodiment, the dielectric space is filled with a low k dielectric material to form a surrounding low k dielectric layer. In this manner, damage to the surrounding low k dielectric layer is mitigated at least because the skeleton layer is removed to form space for the surrounding low k dielectric layer, for example. According to an aspect, the skeleton layer comprises TiN and is removed based at least in part on a wet remove.

The following description and annexed drawings set forth certain illustrative aspects and implementations. These are indicative of but a few of the various ways in which one or more aspects are employed. Other aspects, advantages, or novel features of the disclosure will become apparent from the following detailed description when considered in conjunction with the annexed drawings.

### DESCRIPTION OF THE DRAWINGS

Aspects of the disclosure are understood from the following detailed description when read with the accompanying drawings. It will be appreciated that elements or structures of the drawings are not necessarily be drawn to scale. Accordingly, the dimensions of the various features may be arbitrarily increased or reduced for clarity of discussion.

FIG. 1A is a cross-sectional view of an example set of interconnects for an integrated circuit (IC), according to an embodiment.

FIG. 1B is a cross-sectional view of an example set of interconnects for an integrated circuit (IC), according to an embodiment.

FIG. 2 is a flow diagram of an example method for forming a dielectric layer around a metal line during an integrated circuit (IC) fabrication process, according to an embodiment.

FIG. 3A is a cross-sectional view of an example set of interconnects for an integrated circuit (IC), according to an embodiment.

FIG. 3B is a cross-sectional view of an example set of interconnects for an integrated circuit (IC), according to an embodiment.

FIG. 4A is a cross-sectional view of an example set of interconnects for an integrated circuit (IC), according to an embodiment.

FIG. 4B is a cross-sectional view of an example set of interconnects for an integrated circuit (IC), according to an embodiment.

FIG. 5 is a cross-sectional view of an example set of interconnects for an integrated circuit (IC), according to an embodiment.

FIG. 6 is a flow diagram of an example method for forming a dielectric layer around a metal line during an integrated circuit (IC) fabrication process, according to an embodiment.

FIG. 7 is a flow diagram of an example method for forming a dielectric layer around a metal line during an integrated circuit (IC) fabrication process, according to an embodiment.

FIG. 8A is a cross-sectional view of an example set of interconnects for an integrated circuit (IC), according to an embodiment.

FIG. 8B is a cross-sectional view of an example set of interconnects for an integrated circuit (IC), according to an embodiment.

FIG. 9A is a cross-sectional view of an example set of interconnects for an integrated circuit (IC), according to an embodiment.

FIG. 9B is a cross-sectional view of an example set of interconnects for an integrated circuit (IC), according to an embodiment.

FIG. 10A is a cross-sectional view of an example set of interconnects for an integrated circuit (IC), according to an embodiment.

FIG. 10B is a cross-sectional view of an example set of interconnects for an integrated circuit (IC), according to an embodiment.

FIG. 11A is a cross-sectional view of an example set of interconnects for an integrated circuit (IC), according to an embodiment.

FIG. 11B is a cross-sectional view of an example set of interconnects for an integrated circuit (IC), according to an embodiment.

FIG. 12A is a cross-sectional view of an example set of interconnects for an integrated circuit (IC), according to an embodiment.

FIG. 12B is a cross-sectional view of an example set of interconnects for an integrated circuit (IC), according to an embodiment.

### DETAILED DESCRIPTION

The claimed subject matter is now described with reference to the drawings, wherein like reference numerals are generally used to refer to like elements throughout. In the following description, for purposes of explanation, numerous specific details are set forth in order to provide a thorough understanding of the claimed subject matter. It is evident, however, that the claimed subject matter may be practiced without these specific details. In other instances, structures and devices are illustrated in block diagram form in order to facilitate describing the claimed subject matter.

Generally, an integrated circuit (IC) comprises one or more interconnects, one or more vias, one or more metal lines, and dielectric surrounding the one or more vias and the one or more metal lines. For example, a metal line is connected to a via and a contact. In an embodiment, the metal line and via are surrounded by a surrounding dielectric. In an embodiment, the surrounding dielectric is a surrounding dielectric layer acting as an insulator between different vias and different metal lines. Generally, it is desirable for the surrounding dielectric layer to comprise a low dielectric constant (k). For example, a low dielectric constant value is around 2 to 3. In an embodiment, metal line formation or surrounding dielectric layer formation is associated with a back end of the line (BEOL) fabrication process.

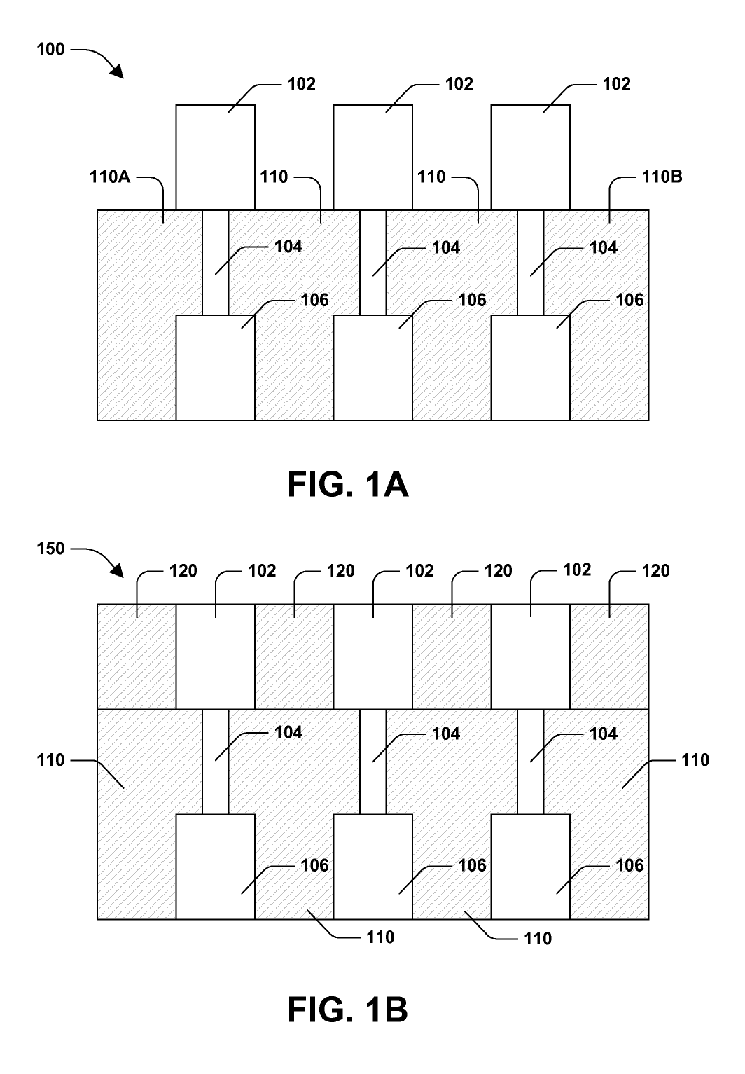

It will be appreciated that a layer is not necessarily planar or horizontally flush in some embodiments. For example, in FIG. 1A, a first surrounding low k dielectric layer 110 is illustrated such that the first surrounding low k dielectric layer 110 surrounds three vias 104. However, in some embodiments, the first surrounding low k dielectric layer 110 is not necessarily horizontally flush with vias 104 or metal lines 102, for example. Similarly, other layers herein are not necessarily planar or horizontally flush in some embodiments. That is, for example, in FIG. 1A, a left first surrounding low k dielectric layer 110A comprises a different height or thickness than a right first surrounding low k dielectric layer 110B in some embodiments. In other embodiments, the left first surrounding low k dielectric layer 110A and the right first surrounding low k dielectric layer 110B comprise a same height, as illustrated in FIG. 1A. Accordingly, dimensions of some of these layers are drawn to be the same for this embodiment, for example. As illustrated herein, layers are thus generally flush, surfaces are uniform, etc., however, there may be slight variations in reality.

FIG. 1A is a cross-sectional view 100 of an example set of interconnects for an integrated circuit (IC), according to an embodiment. In an embodiment, the IC comprises interconnects comprising one or more metal lines 102, one or more vias 104, and one or more contacts 106. In an embodiment, respective metal lines 102 are connected to vias 104 and contacts 106. In an embodiment, a first surrounding low k dielectric layer 110 surrounds one of the vias 104 and one of the contacts 106. In an embodiment, a left first surrounding low k dielectric layer 110A and a first surrounding low k dielectric layer 110 surround another one of the vias 104 and another one of the contacts 106. In an embodiment, a right first surrounding low k dielectric layer 110B and the first surrounding low k dielectric layer 110 surround yet another one of the vias 104 and yet another one of the contacts 106. In an embodiment, metal lines 102 are formed over vias 104 and at least one of the first surrounding low k dielectric layer 110, the left first surrounding low k dielectric layer 110A, or the right first surrounding low k dielectric layer 110B. In an embodiment, the metal lines 102 are formed based at least in part on a skeleton layer comprising TiN. In an embodiment, the first surrounding low k dielectric layer 110 is formed over a substrate layer.

FIG. 1B is a cross-sectional view 150 of an example set of interconnects for an integrated circuit (IC), according to an embodiment. In an embodiment, a second surrounding low k dielectric layer 120 is formed around at least some of the one or more metal lines 102 such that the second surrounding low k dielectric layer 120 is formed over the first surrounding low k dielectric layer 110. In an embodiment, the second surrounding low k dielectric layer 120 comprises a same or at least substantially similar dielectric constant or a same dielectric material as the first surrounding low k dielectric layer 110. In an embodiment, the second surrounding low k dielectric layer 120 comprises a different dielectric constant or a different dielectric material than the first surrounding low k dielectric layer 110. Additionally, in an embodiment, metal lines 102, vias 104, and contacts 106 comprise a same or at least substantially similar metal. However, it will be appreciated that in other embodiment, metal lines 102, vias 104, and contacts 106 comprise different metals.

Therefore, a second low k dielectric layer 120 is formed around a metal line 102 during an integrated circuit (IC) fabrication process, thus enabling the second low k dielectric layer 120 to comprise low capacitance corresponding to a low k value of the second low k dielectric layer 120. In this way R×C performance associated with the IC comprising the second low k dielectric layer 120 is improved. In an embodiment, a capacitance associated with the second low k dielectric layer 120 is improved by 15%, for example.

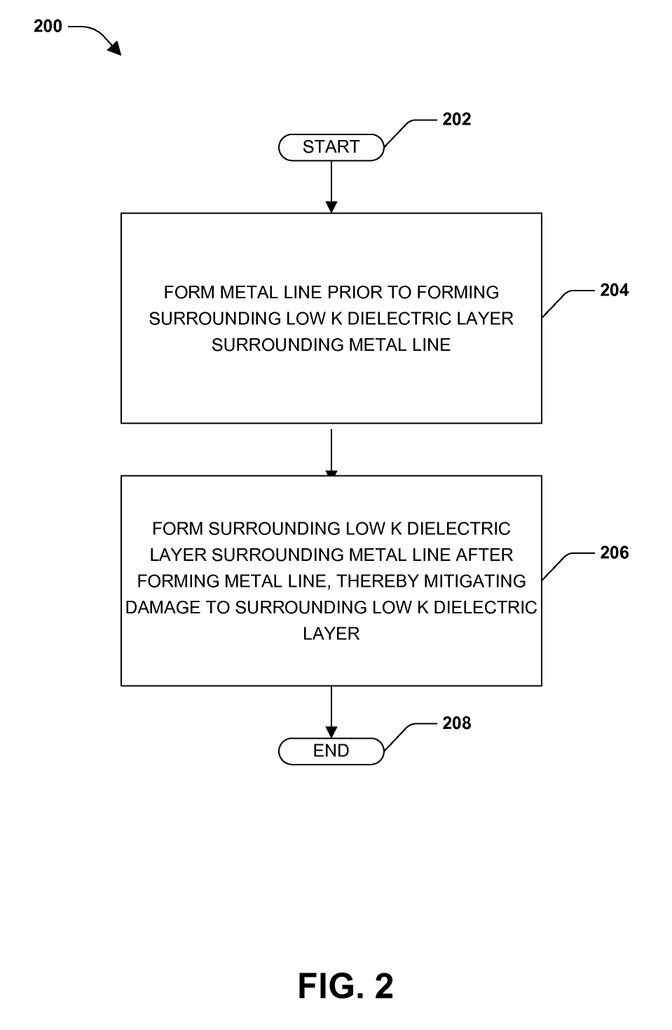

FIG. 2 is a flow diagram of an example method 200 for forming a dielectric layer around a metal line during an integrated circuit (IC) fabrication process, according to an embodiment. At 202, the method 200 begins, and at 204, a metal line 102 is formed prior to forming a surrounding low k dielectric layer surrounding the metal line. In an embodiment, the surrounding low k dielectric layer surrounding the metal line is the second low k dielectric layer 120 of FIG. 1B. At 206, the low k dielectric layer surrounding the metal line 102, such as the second low k dielectric layer 120 is formed after forming the metal line 102. Therefore, damage to the surrounding low k dielectric layer 120 is mitigated at least because the surrounding low k dielectric layer 120 is not subject to plasma during a trench etch, for example. At 208, the method 200 ends.

In an embodiment, the metal line 102 is formed by filling a trench space in a skeleton layer with metal. In an embodiment, the skeleton layer is removed to form a dielectric space, the dielectric space in a different location than the trench space. According to an aspect, the surrounding low k dielectric layer 120 is formed by filling the dielectric space with a low k dielectric material. Additionally, the skeleton layer is removed by conducting a wet remove. In an embodiment, the metal line 102 is formed based at least in part on a skeleton layer comprising TiN.

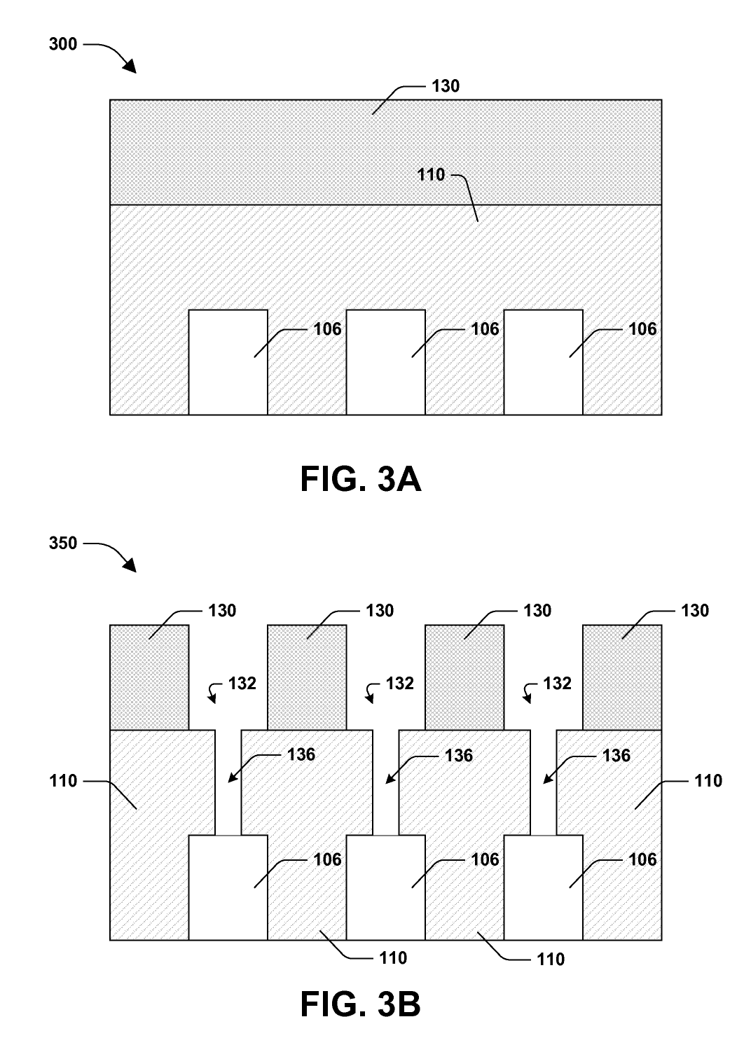

FIG. 3A is a cross-sectional view 300 of an example set of interconnects for an integrated circuit (IC), according to an embodiment. In an embodiment, a skeleton layer 130 is formed over a first surrounding low k dielectric layer 110. In an embodiment, the first surrounding low k dielectric layer 110 is formed over one or more contacts 106. It will be appreciated that at least a portion of the example set of interconnects are formed from the one or more contacts 106.

FIG. 3B is a cross-sectional view 350 of an example set of interconnects for an integrated circuit (IC), according to an embodiment. In an embodiment, one or more trench spaces 132 are created in the skeleton layer 130 and one or more via spaces 136 are created in the first surrounding low k dielectric layer 110. For example, a trench space 132 is surrounded by the skeleton layer 130. For example, a via space 136 is surrounded by the first surrounding low k dielectric layer 110. It will be appreciated that the skeleton layer 130 comprises one or more portions in FIG. 3B, but is a single continuous portion in FIG. 3A. Similarly, the first surrounding low k dielectric layer 110 comprises one or more portions in FIG. 3B, but is a single portion in FIG. 3A. In an embodiment, the skeleton layer 130 comprises TiN and undergoes lithography or etching to form the one or more trench spaces 132. Similarly, in an embodiment, the one or more via spaces 136 are formed via lithography or etching on the first surrounding low k dielectric layer 110. In an embodiment, the first surrounding low k dielectric layer 110 comprises a low k dielectric material comprising a dielectric constant around two to three, for example. In an embodiment, at least a portion of the example set of interconnects for the IC is formed from one or more of the contacts 106.

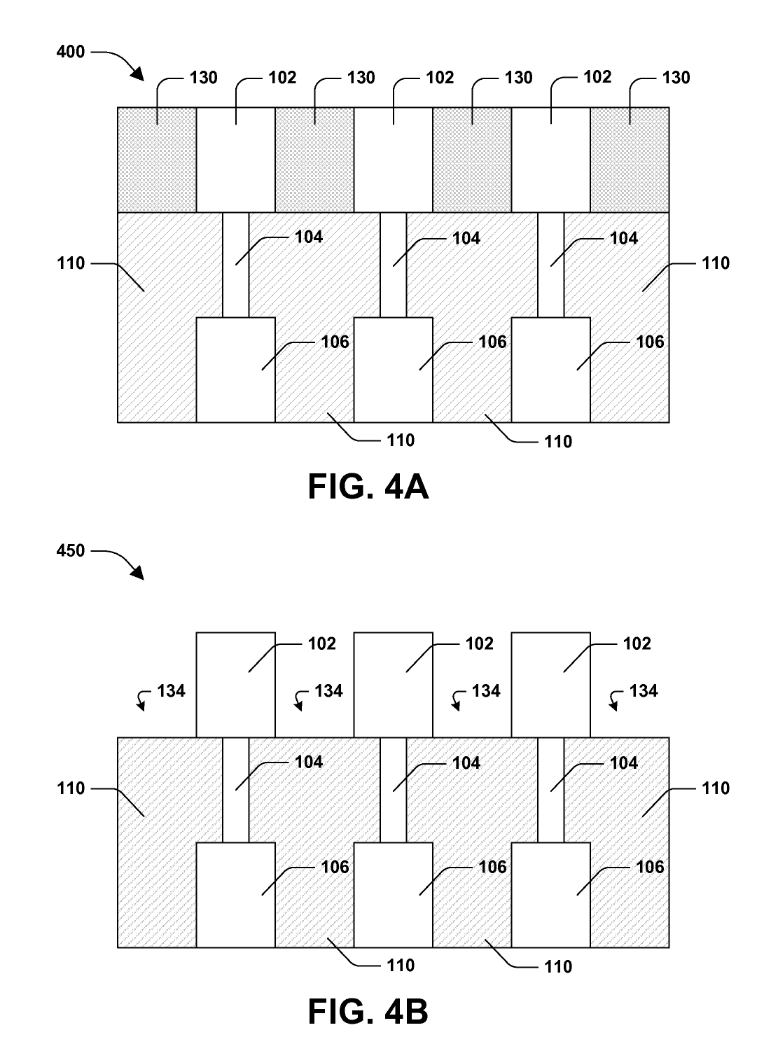

FIG. 4A is a cross-sectional view 400 of an example set of interconnects for an integrated circuit (IC), according to an embodiment. In an embodiment, one or more vias 104 and one or more metal lines 102 are formed by filling the one or more via spaces 136 of FIG. 3B and the one or more trench spaces 132 of FIG. 3B with a first metal and a second metal, respectively. In an embodiment, the first metal comprises a same material as the second metal. In an embodiment the interconnects of FIG. 4A are formed of the one or more contacts 106, the one or more vias 104, and the one or more metal lines 102. In an embodiment, the first surrounding low k dielectric layer 110 acts as a supporting frame for formation of the vias 104. In an embodiment, the skeleton layer 130 acts as a supporting frame for formation of the metal lines 102.

FIG. 4B is a cross-sectional view 450 of an example set of interconnects for an integrated circuit (IC), according to an embodiment. In an embodiment, the skeleton layer 130 of FIG. 4A is removed to create one or more dielectric spaces 134. It will be appreciated that the one or more dielectric spaces 134 are in a different location than the one or more trench spaces 132 of FIG. 3B. In an embodiment, the skeleton layer 130 is removed using a wet remove process. For example, the wet remove process is conducted such that the metal lines 102 and the first surrounding low k dielectric layer 110 are generally undamaged. In an embodiment, the wet remove does not affect or does not appreciably affect a k value associated with the first surrounding low k dielectric layer 110. In an embodiment, the set of interconnects is formed of contacts 106, vias 104, and metal lines 102. In an embodiment, the vias 104 and the contacts 106 are surrounded by the first surrounding low k dielectric layer 110. In an embodiment, the metal lines 102 are surrounded by the one or more dielectric spaces 134.

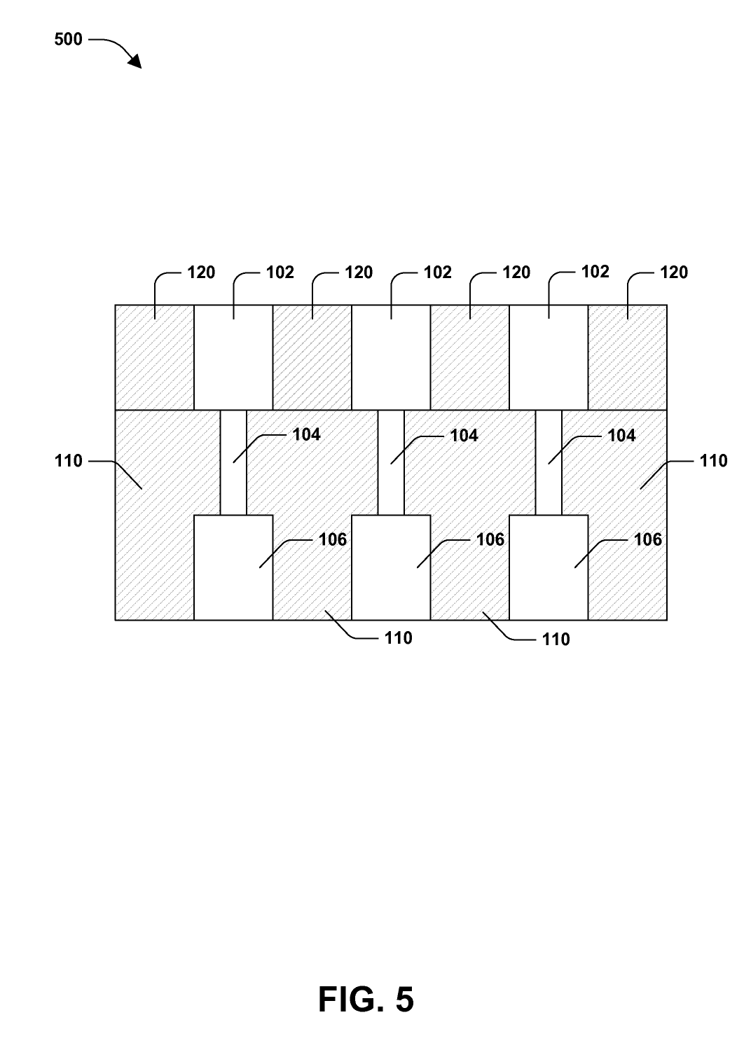

FIG. 5 is a cross-sectional view 500 of an example set of interconnects for an integrated circuit (IC), according to an embodiment. In an embodiment, a second surrounding low k dielectric layer 120 is formed by filling one or more of the dielectric spaces 134 of FIG. 4B with a low k dielectric material. In an embodiment, one or more metal lines 102 provide support for the second surrounding low k dielectric layer 120 during formation, for example. In an embodiment, the second surrounding low k dielectric layer 120 comprises a same or at least substantially similar dielectric constant or a same dielectric material as the first surrounding low k dielectric layer 110. In an embodiment, the second surrounding low k dielectric layer 120 is formed over the first surrounding low k dielectric layer 110. Accordingly, the example set of interconnects is formed from contacts 106, vias 104, and metal lines 102. In this way, dielectric 110 and 120 is formed around the metal lines 102 and vias 104, while mitigating damage to the dielectric 110 and 120 during formation. For example, little to no shift in dielectric constant (k) is associated with the first surrounding low k dielectric layer 110 or the second surrounding low k dielectric layer 120 at least because the metal lines 102 are formed prior to the second surrounding low k dielectric layer 120.

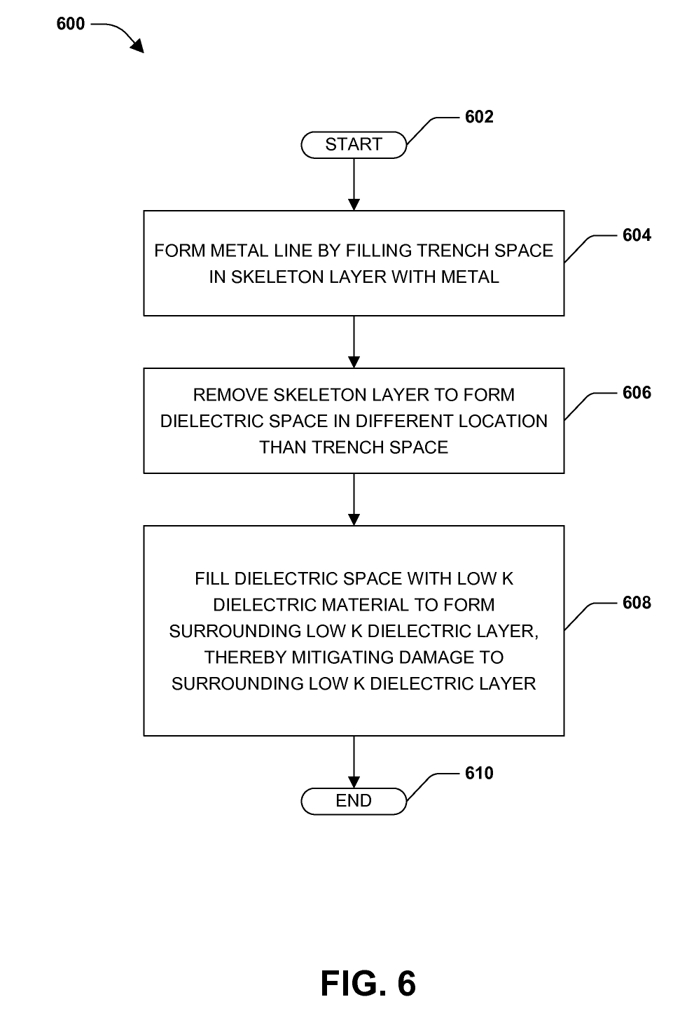

FIG. 6 is a flow diagram of an example method 600 for forming a dielectric layer around a metal line during an integrated circuit (IC) fabrication process, according to an embodiment. In an embodiment, the method 600 starts at 602 and a metal line 102 is formed by filling a trench space 132 in a skeleton layer 130 with metal. At 606, the skeleton layer 130 is removed to form a dielectric space 134 such that the dielectric space 134 is in a different location than the trench space 132. At 608, the dielectric space 134 is filled with a low k dielectric material to form a surrounding low k dielectric layer, such as the second surrounding low k dielectric layer 120 of FIG. 5. In this way, damage to the surrounding low k dielectric layer is mitigated. At 610, the method 600 ends.

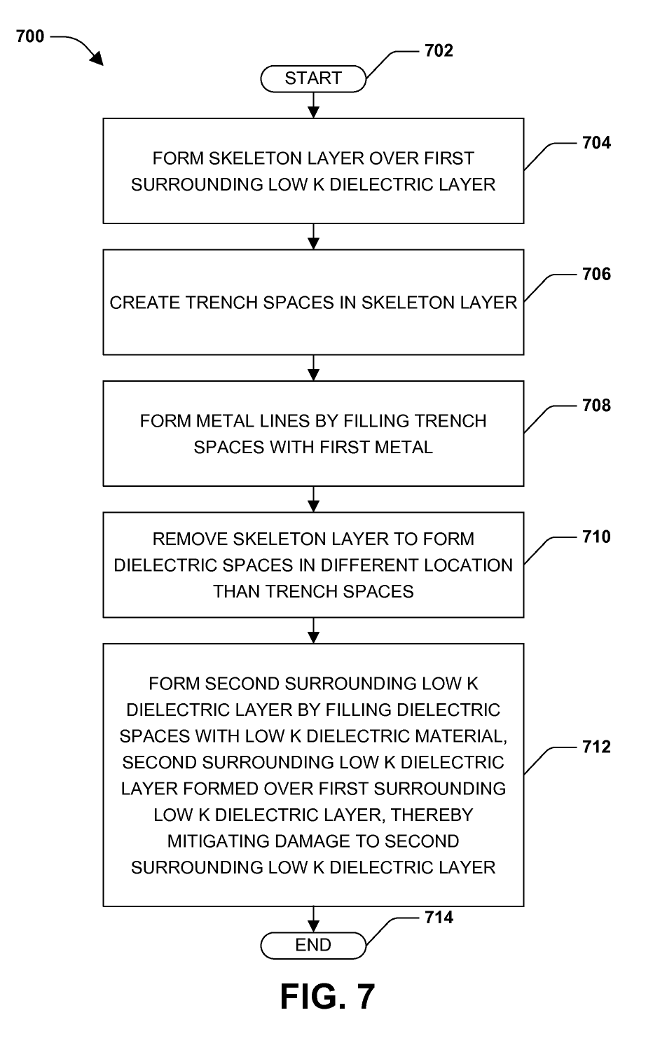

FIG. 7 is a flow diagram of an example method 700 for forming a dielectric layer around a metal line during an integrated circuit (IC) fabrication process, according to an embodiment. At 702, the method 700 begins, and a skeleton layer 130 is formed over a first surrounding low k dielectric layer 110 at 704. In an embodiment, one or more trench spaces 132 are created in the skeleton layer 130 at 706. At 708, one or more metal lines 102 are formed by filling the one or more trench spaces 132 with a first metal. At 710, the skeleton layer 130 is removed to form one or more dielectric spaces 134 such that the dielectric spaces 134 are in different locations than the trench spaces 132. At 712, a second surrounding low k dielectric layer 120 is formed by filling the one or more dielectric spaces 134 with a low k dielectric material. In an embodiment, the first surrounding low k dielectric layer 110 and the second surrounding low k dielectric layer 120 comprise a same or at least substantially similar dielectric constant or a same low k dielectric material. For example, in an embodiment, the first surrounding low k dielectric layer 110 and the second surrounding low k dielectric layer 120 comprise a dielectric constant (k) of 2.5. In an embodiment, the second surrounding low k dielectric layer 120 is formed over the first surrounding low k dielectric layer 110 and around or surrounding the one or more metal lines 102. In this way damage to at least one of the first surrounding low k dielectric layer 110 or the second surrounding low k dielectric layer 120 is mitigated, at least because the second surrounding low k dielectric layer 120 does not undergo an etch or lithography process, for example.

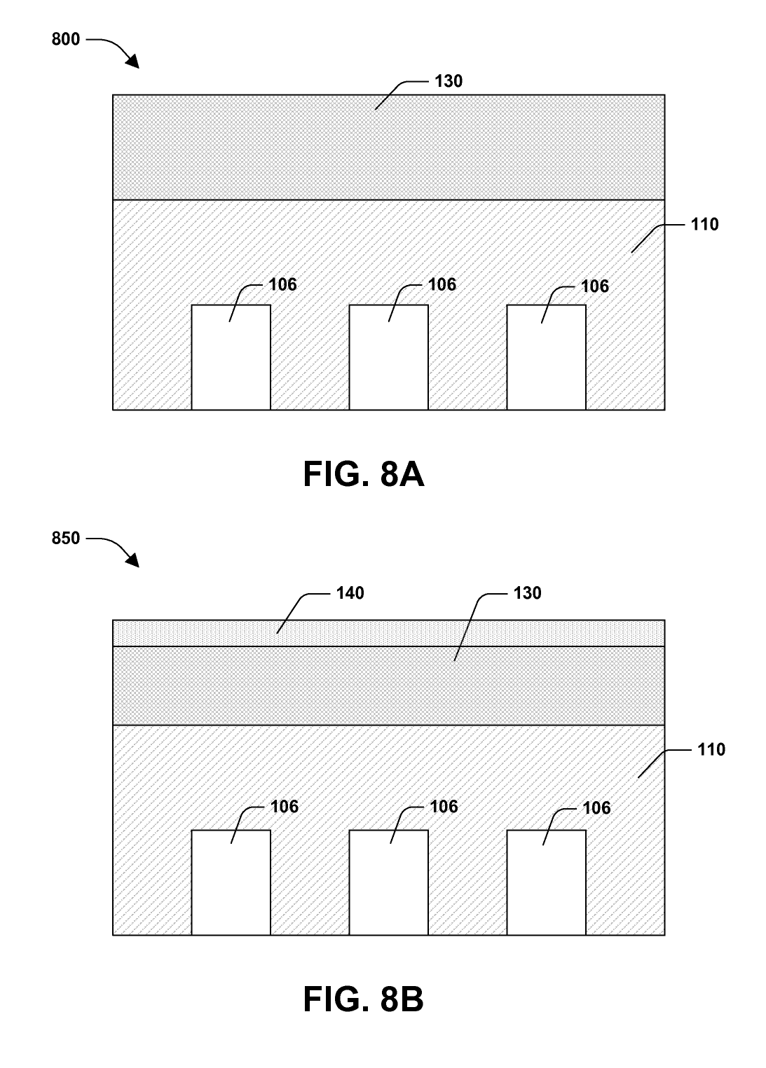

FIG. 8A is a cross-sectional view 800 of an example set of interconnects for an integrated circuit (IC), according to an embodiment. In an embodiment, a first surrounding low k dielectric layer 110 is formed over or surrounding contacts 106. Additionally, a skeleton layer 130 is formed over the first surrounding low k dielectric layer 110. In an embodiment, the skeleton layer 130 is formed of TiN. In an embodiment, the first surrounding low k dielectric layer 110 is formed over a substrate layer. FIG. 8B is a cross-sectional view 850 of an example set of interconnects for an integrated circuit (IC), according to an embodiment. For example, a hard mask layer 140 is formed over the skeleton layer 130 of FIG. 8A, the first surrounding low k dielectric layer 110, and gates 106.

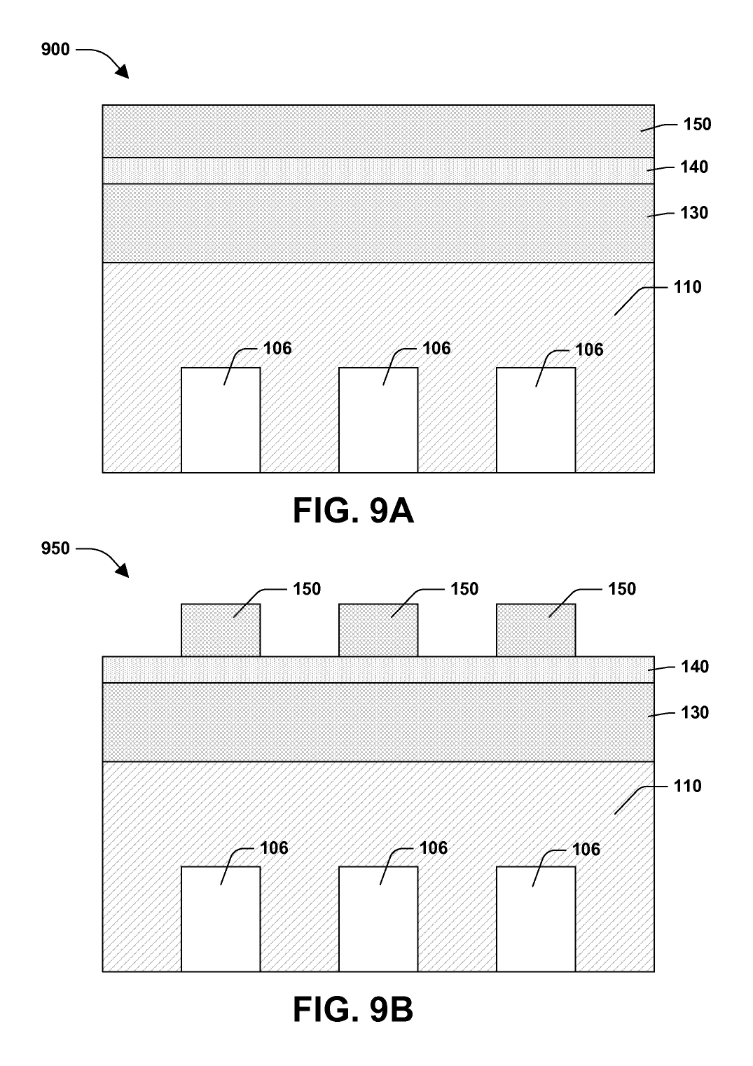

FIG. 9A is a cross-sectional view 900 of an example set of interconnects for an integrated circuit (IC), according to an embodiment. In an embodiment, photo resist 150 is spun on or layered over the hard mask layer 140, the skeleton layer 130, the first surrounding low k dielectric layer 110, and contacts 106. FIG. 9B is a cross-sectional view 950 of an example set of interconnects for an integrated circuit (IC), according to an embodiment. In an embodiment, photo resist 150 is patterned. For example, the patterning is achieved using a mask. Therefore, photo resist 150 covers at least some portions of the hard mask layer 140, but does not cover other portions of the hard mask layer 140. In an embodiment, the hard mask layer 140 is formed over the skeleton layer 130, the first surrounding low k dielectric layer 110, and contacts 106.

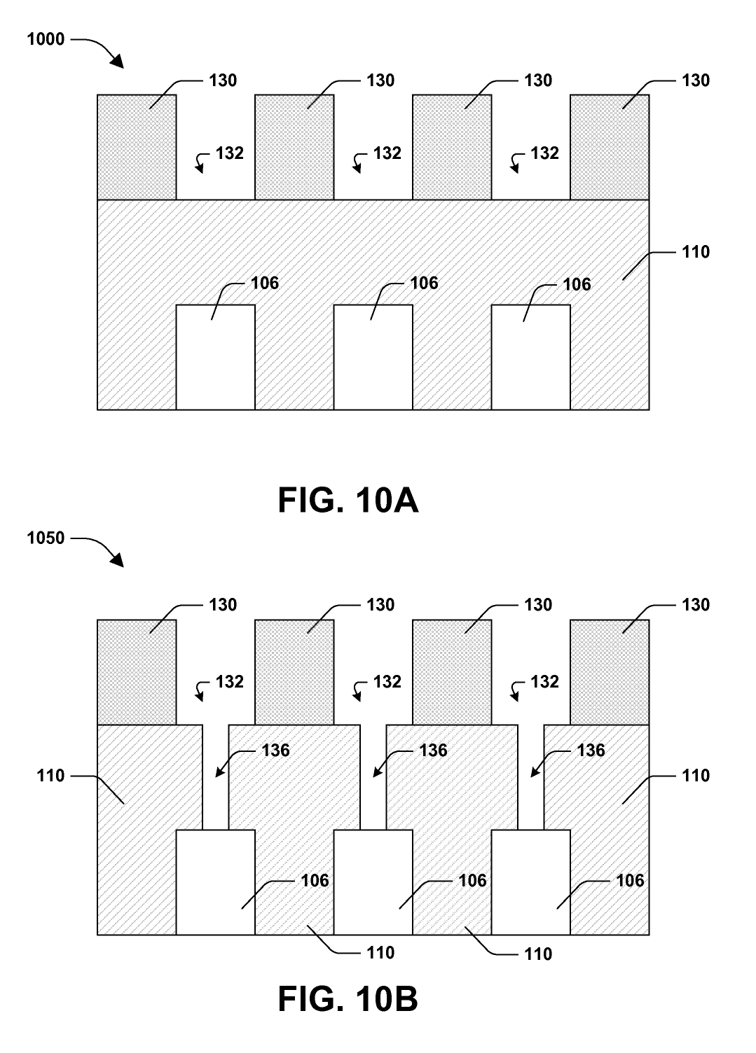

FIG. 10A is a cross-sectional view 1000 of an example set of interconnects for an integrated circuit (IC), according to an embodiment. In an embodiment, the patterned photo resist 150 of FIG. 9B is used to pattern the skeleton layer 130. In other words, the patterned photo resist 150 is used to form one or more trench spaces 132 in the skeleton layer 130 by patterning the skeleton layer 130. The patterned photo resist 150 is then subsequently removed, as illustrated, such as by acid washing, for example. It will be appreciated that skeleton layer 130 comprises one or more portions in FIG. 10A, but merely a single portion in FIG. 9B, before patterning lithography associated with formation of the one or more trench spaces 132. It will be appreciated that the lithography associated with formation of the trench spaces 132 is conducted such that the first surrounding low k dielectric layer 110 is generally unaffected. Contacts 106 thus remain surrounded by the first surrounding low k dielectric layer 110. FIG. 10B is a cross-sectional view 1050 of an example set of interconnects for an integrated circuit (IC), according to an embodiment. In an embodiment, lithography or etching is performed on the first surrounding low k dielectric layer 110 to form one or more via spaces 136. In an embodiment, contacts 106 are surrounded by the first surrounding low k dielectric layer 110 on the sides, and located under the respective via spaces 136. Trench spaces 132 are located above the via spaces 136, and surrounded by the skeleton layer 130 on the sides.

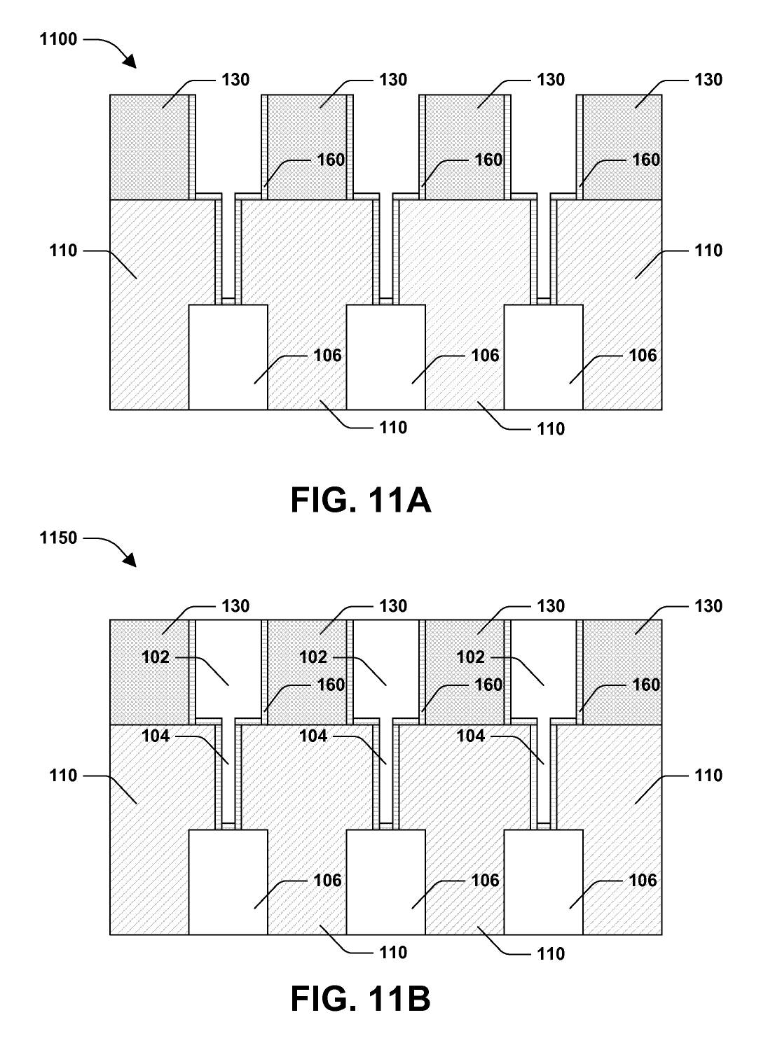

FIG. 11A is a cross-sectional view 1100 of an example set of interconnects for an integrated circuit (IC), according to an embodiment. In an embodiment, a barrier 160 is formed around a perimeter of a via space 136 and trench space 132 such that a “shell” is formed for a metal line 102 and a via 104 not yet formed. In an embodiment, the barrier 160 is formed along a wall of the skeleton layer 130, a top surface of the first surrounding low k dielectric layer 110, and a wall of the first surrounding low k dielectric layer 110. In an embodiment, the barrier 160 is formed by growth or deposition techniques or both growth and deposition techniques. In an embodiment, the barrier comprises a dielectric material and has a thickness approximately 1/10^{th} the thickness of a via 104 or approximately 1/50^{th} the thickness of a metal line, for example. In an embodiment, a contact 106 is located below the barrier 160. FIG. 11B is a cross-sectional view 1150 of an example set of interconnects for an integrated circuit (IC), according to an embodiment. In an embodiment, one or more metal lines 102 and vias 104 are formed by filling one or more trench spaces 132 of FIG. 10B and one or more via spaces 136 of FIG. 10B with metal. In an embodiment, one or more metal lines 102 are formed by filling the one or more trench spaces 132 with a first metal. In an embodiment, one or more vias 104 are formed by filling the one or more via spaces 136 with a second metal. It will be appreciated that the first metal is the second metal in some embodiments. In an embodiment, formation of the vias 104 is enabled by support from the first surrounding low k dielectric layer 110 and the contacts 106. In an embodiment, formation of the metal lines 102 is enabled by support from the skeleton layer 130. In an embodiment, formation of the vias 104 or the metal lines 102 is enabled by support from the barriers 160.

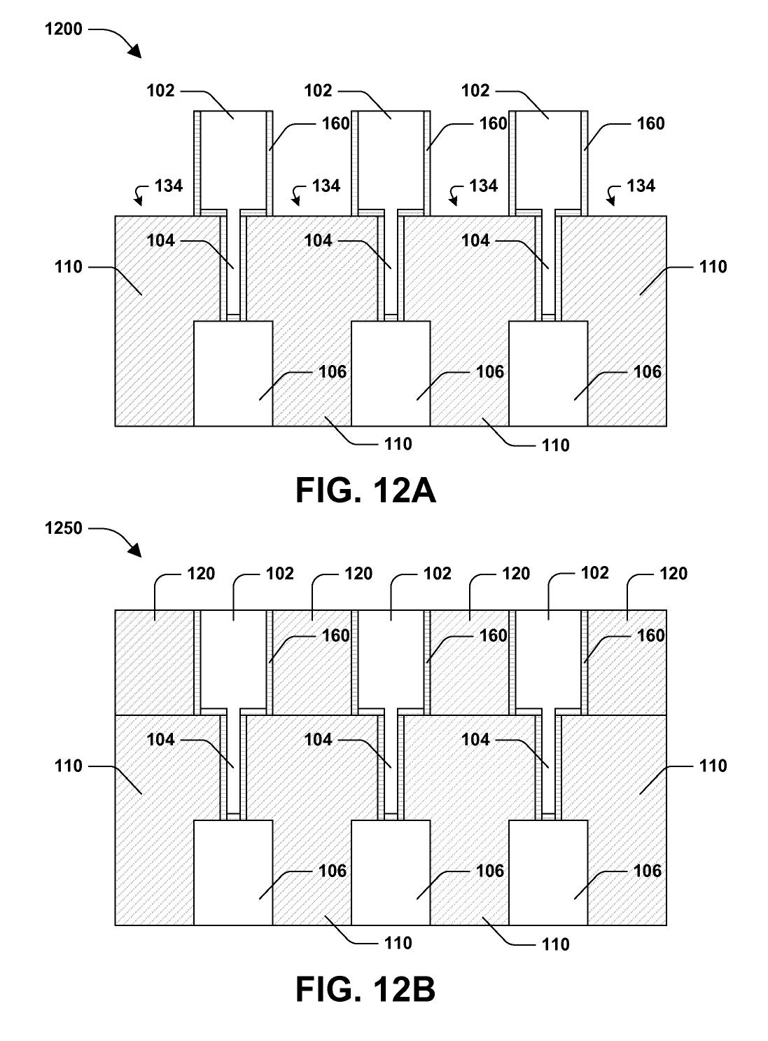

FIG. 12A is a cross-sectional view 1200 of an example set of interconnects for an integrated circuit (IC), according to an embodiment. In an embodiment, the skeleton layer 130 is removed, and metal lines 102 are self supporting. For example the skeleton layer 130 is removed based at least in part on a wet remove. In an embodiment, removal of the skeleton layer 130 forms one or more dielectric spaces 134. In an embodiment, the skeleton layer 130 is removed using a wet remove process, and generally does not damage the barrier 160, metal lines 102, the first surrounding low k dielectric layer 110. FIG. 12B is a cross-sectional view 1250 of an example set of interconnects for an integrated circuit (IC), according to an embodiment. In an embodiment, a second surrounding low k dielectric layer 120 is formed by filling one or more of the dielectric spaces 134 with a low k dielectric material. In an embodiment, the second surrounding low k dielectric layer 120 is formed by growth or deposition techniques or both growth and deposition techniques. In an embodiment, the first surrounding low k dielectric layer 110 comprises a same or at least substantially similar dielectric constant or same dielectric material as the second surrounding low k dielectric layer 120. In an embodiment, the metal lines 102 comprise a same metal as the vias 104 and the contacts 106. In an embodiment, the barriers 160 are formed between the metal lines 102 and the surrounding low k dielectric layers 110 and 120. In this way, the second surrounding low k dielectric layer 120 is formed to surround the metal lines 102, thereby mitigating damage to the second surrounding low k dielectric layer 120 at least because the second surrounding low k dielectric layer 120 is formed after the metal lines 102 are formed.

According to an aspect, a method for forming a dielectric layer around a metal line during an integrated circuit (IC) fabrication process is provided, comprising forming a metal line prior to forming a surrounding low k dielectric layer surrounding the metal line. The method comprises forming the surrounding low k dielectric layer surrounding the metal line after forming the metal line, thereby mitigating damage to the surrounding low k dielectric layer.

According to an aspect, a method for forming a dielectric layer around a metal line during an integrated circuit (IC) fabrication process is provided, comprising forming a metal line by filling a trench space in a skeleton layer with metal. The method comprises removing the skeleton layer to form a dielectric space, the dielectric space in a different location than the trench space. Additionally, the method comprises filling the dielectric space with a low k dielectric material to form a surrounding low k dielectric layer, thereby mitigating damage to the surrounding low k dielectric layer.

According to an aspect, a method for forming a dielectric layer around a metal line during an integrated circuit (IC) fabrication process is provided, comprising forming a skeleton layer over a first surrounding low k dielectric layer. The method comprises creating one or more trench spaces in the skeleton layer and forming one or more metal lines by filling at least some of the one or more trench spaces with a first metal. In an embodiment, the method comprises removing the skeleton layer to form one or more dielectric spaces, the one or more dielectric spaces in a different location than the one or more trench spaces. In an embodiment, the method comprises forming a second surrounding low k dielectric layer by filling at least some of the one or more dielectric spaces with low k dielectric material, the second surrounding low k dielectric layer formed over the first surrounding low k dielectric layer. In this way, damage to the second surrounding low k dielectric layer is mitigated.

Although the subject matter has been described in language specific to structural features or methodological acts, it is to be understood that the subject matter of the appended claims is not necessarily limited to the specific features or acts described above. Rather, the specific features and acts described above are disclosed as example forms of implementing the claims.

Various operations of embodiments are provided herein. The order in which some or all of the operations are described should not be construed as to imply that these operations are necessarily order dependent. Alternative ordering will be appreciated by one skilled in the art having the benefit of this description. Further, it will be understood that not all operations are necessarily present in each embodiment provided herein.

It will be appreciated that layers, features, elements, such as the metal line, via, contact, first surrounding low k dielectric layer, second surrounding low k dielectric layer, hard mask, photo resist, barrier, skeleton, trench space, dielectric space, via space, etc. depicted herein are illustrated with particular dimensions relative to one another, such as structural dimensions or orientations, for example, for purposes of simplicity and ease of understanding and that actual dimensions of the same differ substantially from that illustrated herein, in some embodiments. Additionally, a variety of techniques exist for forming the layers features, elements, etc. mentioned herein, such as electro chemical plating (ECP), etching techniques, wet remove techniques, implanting techniques, doping techniques, spin-on techniques, sputtering techniques such as magnetron or ion beam sputtering, growth techniques, such as thermal growth or deposition techniques such as chemical vapor deposition (CVD), for example.

Moreover, “exemplary” is used herein to mean serving as an example, instance, illustration, etc., and not necessarily as advantageous. As used in this application, “or” is intended to mean an inclusive “or” rather than an exclusive “or”. In addition, “a” and “an” as used in this application are generally be construed to mean “one or more” unless specified otherwise or clear from context to be directed to a singular form. Also, at least one of A and B and/or the like generally means A or B or both A and B. Furthermore, to the extent that “includes”, “having”, “has”, “with”, or variants thereof are used in either the detailed description or the claims, such terms are intended to be inclusive in a manner similar to the term “comprising”.

Also, although the disclosure has been shown and described with respect to one or more implementations, equivalent alterations and modifications will occur to others skilled in the art based upon a reading and understanding of this specification and the annexed drawings. The disclosure includes all such modifications and alterations and is limited only by the scope of the following claims.

What is claimed is:

1. A method for forming a dielectric layer around a metal line during an integrated circuit (IC) fabrication process, comprising:
forming a metal line prior to forming a surrounding low k dielectric layer surrounding the metal line; and
forming the surrounding low k dielectric layer surrounding the metal line after forming the metal line, thereby mitigating damage to the surrounding low k dielectric layer.

2. The method of claim 1, forming the metal line comprising filling a trench space in a skeleton layer with metal.

3. The method of claim 2, comprising removing the skeleton layer to form a dielectric space, the dielectric space in a different location than the trench space.

4. The method of claim 3, forming the surrounding low k dielectric layer comprising filling the dielectric space with a low k dielectric material.

5. The method of claim 3, removing the skeleton layer comprising conducting a wet remove.

6. The method of claim 1, comprising forming the metal line based at least in part on a skeleton layer comprising TiN.

7. A method for forming a dielectric layer around a metal line during an integrated circuit (IC) fabrication process, comprising:
forming a metal line by filling a trench space in a skeleton layer with metal;
removing the skeleton layer to form a dielectric space, the dielectric space in a different location than the trench space; and
filling the dielectric space with a low k dielectric material to form a surrounding low k dielectric layer, thereby mitigating damage to the surrounding low k dielectric layer.

8. The method of claim 7, comprising forming a barrier between the metal line and the surrounding low k dielectric layer.

9. The method of claim 7, comprising forming the skeleton layer of TiN.

10. The method of claim 7, comprising removing the skeleton layer based at least in part on a wet remove.

11. A method for forming a dielectric layer around a metal line during an integrated circuit (IC) fabrication process, comprising:
forming a skeleton layer over a first surrounding low k dielectric layer;
creating one or more trench spaces in the skeleton layer;
forming one or more metal lines by filling at least some of the one or more trench spaces with a first metal;
removing the skeleton layer to form one or more dielectric spaces, the one or more dielectric spaces in a different location than the one or more trench spaces; and
forming a second surrounding low k dielectric layer by filling at least some of the one or more dielectric spaces with low k dielectric material, the second surrounding low k dielectric layer formed over the first surrounding low k dielectric layer, thereby mitigating damage to the second surrounding low k dielectric layer.

12. The method of claim 11, comprising forming a hard mask layer over the skeleton layer.

13. The method of claim 12, comprising layering a photo resist layer over the hard mask layer.

14. The method of claim 13, comprising patterning the photo resist layer using a mask.

15. The method of claim 14, comprising patterning the skeleton layer based at least in part on the patterned photo resist layer.

16. The method of claim 15, comprising conducting via lithography and via etch on the first surrounding low k dielectric layer to form one or more via spaces.

17. The method of claim 16, comprising forming one or more vias by filling at least some of the one or more via spaces with a second metal.

18. The method of claim 11, comprising forming the skeleton layer of TiN.

19. The method of claim 11, comprising removing the skeleton layer based at least in part on a wet remove.

20. The method of claim 11, comprising forming the first surrounding low k dielectric layer over a substrate layer.
